(19) United States
(12) Patent Application Publication
(10) Pub. No.: US 2026/0227870 A1
(43) Pub. Date: Aug. 6, 2026

(54) TOUCH-SENSITIVE SWITCHING APPARATUS FOR A CONTROL DEVICE

(71) Applicant: Siemens Healthineers AG, Forchheim (DE)

(72) Inventor: Ulrich BATZER, Spardorf (DE)

(73) Assignee: Siemens Healthineers AG, Forchheim (DE)

(21) Appl. No.: 19/529,197

(22) Filed: Feb. 4, 2026

(30) Foreign Application Priority Data
Feb. 5, 2025 (DE) 10 2025 104 174.1

(51) Int. Cl. G06F 3/041; G06F 1/16; G06F 3/01; G06F 3/044

(52) U.S. Cl. CPC G06F 3/04146; G06F 1/1656; G06F 3/016; G06F 3/0447; G06F 2203/014; G06F 2203/04103

(57) ABSTRACT

One or more example embodiments relates to a touch-sensitive switching apparatus for a control device with a touch display, the touch-sensitive switching apparatus comprising an attachment area with the underside of which the touch-sensitive switching apparatus can be attached to a touch display in the manner intended, and a plurality of activation elements, each activation element comprising a transparent pressure area with an electrically conductive contact element and an elastic spacing area which completely surrounds the pressure area and keeps it away from the plane of the attachment area, the touch-sensitive switching apparatus being transparent at least in the pressure area so that an underlying touch display is visible, the surface of the touch-sensitive switching apparatus being at least water-resistant so that no liquid can penetrate under the pressure area from this surface.

### CROSS-REFERENCE TO RELATED APPLICATION(S)

The present application claims priority under 35 U.S.C. § 119 to German Patent Application No. 10 2025 104 174.1, filed Feb. 5, 2025, the entire contents of which is incorporated herein by reference.

### FIELD

One or more example embodiments relates to a touch-sensitive switching apparatus for a control device, a control apparatus and a method for the production of a control apparatus.

### RELATED ART

In recent times, medical devices have been controlled via remote controls with a touch-sensitive screen (a so-called “touch display” or “touchscreen”). However, this may cause problems if the screen detects signals which have not been deliberately entered by a user and originate from, for example, spilled conductive liquids. In particular, capacitive touch displays are at risk of triggering false touch events due to conductive liquids such as blood or NaCl solution.

For example, imaging diagnostic systems have safety-critical

functions such as, for example, the movement of C-arms or the triggering of radiation, which can lead to injuries if operated incorrectly. These functions must therefore not be triggered by particular circumstances in the working environment, such as spilled liquids.

For particular functions, it is even necessary to execute them in a functionally safe manner so that spontaneous electronic or hardware malfunctions do not pose any danger. This is achieved via redundant querying in most cases.

Usually, capacitive touch displays are not used in moisture-related areas. Modern capacitive touch displays offer the possibility of switching from a particularly vulnerable multitouch operation to a less vulnerable single-touch operation, in other words, an operation which requires only one signal at one point on the display and not multiple signals. However, this is not functional with conductive liquids even under the best conditions; the activation of GUI elements which are covered with conductive liquids is not possible.

A particular embodiment of a control device with a touch display and a control element applied thereto is described in EP 3 355 474 A1. However, this does not allow for optimal operation and does not offer the special advantages of a touch display.

### SUMMARY

One or more example embodiments provides a touch-sensitive switching apparatus for a control device, a control apparatus and a method for the production of a control apparatus with which the disadvantages described above are avoided.

### BRIEF DESCRIPTION OF THE DRAWINGS

The invention is explained again in more detail hereinafter with reference to the accompanying figures on the basis of exemplary embodiments. In the various figures the same components are marked with identical reference characters. The figures are not to scale as a rule.

FIG. 1 illustrates a CT system with a control apparatus according to one or more example embodiments,

FIG. 2 illustrates a example of a touch-sensitive switching apparatus according to one or more example embodiments in side view,

FIG. 3 illustrates a example of the function of a touch-sensitive switching apparatus according to one or more example embodiments in side view,

FIG. 4 illustrates a example of a touch-sensitive switching apparatus according to one or more example embodiments with special contact elements in side view,

FIG. 5 illustrates a further example of a touch-sensitive switching apparatus according to one or more example embodiments in side view,

FIG. 6 illustrates a further example of a touch-sensitive switching apparatus according to one or more example embodiments in side view, and

FIG. 7 illustrates a control apparatus with a touch-sensitive switching apparatus according to one or more example embodiments.

### DETAILED DESCRIPTION

A touch-sensitive switching apparatus according to one or more example embodiments is intended for a control device with a touch display. The touch-sensitive switching apparatus comprises an attachment area with the underside of which the touch-sensitive switching apparatus can be attached to a touch display in the manner intended, and a plurality of activation elements (buttons). Each activation element comprises a transparent pressure area with an electrically conductive contact element and an elastic spacing area which completely surrounds the pressure area and keeps it away from the plane of the attachment area. The touch-sensitive switching apparatus is transparent at least in the pressure area so that an underlying touch display is visible. The surface of the touch-sensitive switching apparatus is at least water-resistant so that no liquid can penetrate under the pressure area from this surface.

The touch-sensitive switching apparatus is specifically designed for use on a touch display. It should provide a user-friendly, reliable and weather-resistant user interface which prevents unwanted activations of functions as a result of liquids on the switching apparatus. For a better understanding, it can be assumed that the touch-sensitive switching apparatus is made of a silicon mat in which the activation elements are formed as protrusions. The touch-sensitive switching apparatus has activation elements (at least two, but also five or more) which serve as buttons, and an attachment area around the activation elements with which it can be attached to a touch display.

The attachment area essentially constitutes the underside of the touch-sensitive switching apparatus or the intermediate space between the activation elements and the outer edge around the activation elements. It is specifically designed to be directly attached to a touch display. This surface ensures a safe and, in particular, also water-resistant connection between the touch-sensitive switching apparatus and the touch display. Adhesive or double-sided adhesive tape can be attached to the attachment area for this purpose.

Each activation element comprises a transparent pressure area and an elastic spacing area which is preferably also transparent. The transparent pressure area enables visual perception of the underlying touch display. The elastic spacing area keeps the pressure area at a distance from the plane of the attachment area. “Elastic” means that the pressure area can be pressed down while deforming the spacing area (i.e., toward the underside), and at the same time the spacing area exerts a counterforce against the downward force, in particular a force greater than 0.4 N.

During operation (i.e., when the touch-sensitive switching apparatus is applied to the touch display of a control apparatus), the respective function of the activation elements is displayed on the touch display below the pressure areas. This can be done using an icon, or a text, or a particular color. The transparent pressure area enables a user to visually recognize the respective function based on the display of the touch display. In order that a liquid such as blood or NaCl solution cannot trigger a function, the pressure area of each activation element is kept away from the touch display via the spacing area. For example, a button-shaped silicone mold can contain a pressure area and a spacing area.

When the user presses on the transparent pressure area of an activation unit, they overcome the distance specified by the elastic spacing area, and come into contact with the touch display, which results in an action. At the same time, the elasticity of the spacer prevents a permanent connection, so that the pressure area returns to its original position after release.

For reliable activation, the pressure area is equipped with an electrically conductive contact element. This contact element performs the actual activation function for the touch display. It should be noted here that just placing a finger on the pressure area (without pressing down) can trigger a signal in the contact element. This can be used for redundancy or activation of (non-critical) auxiliary functions.

An activation element could, for example, be formed from a transparent plastic part (pressure area) which is coated with a thin layer of conductive material. It is surrounded by an elastic, ring-shaped rubber or an elastic edge which keeps it at a distance above a touch display. The underside of the ring-shaped rubber is the attachment area.

The entire surface of the touch-sensitive switching apparatus, including the attachment area and the activation elements, is at least water-resistant. To this end, the touch-sensitive switching apparatus can be made of a water-resistant material, for example, as a silicon mat, or be provided with a water-resistant coating. This prevents the penetration of liquids under the pressure area, which ensures safe functionality. Repelling moisture prevents a critical function from being triggered on a touch display with an applied touch-sensitive switching apparatus by a conductive liquid located on the touch-sensitive switching apparatus. Without active depression of a pressure area via a force being applied from above, no critical function can be activated.

“Water-resistant” means that no liquid can penetrate the touch-sensitive switching apparatus (i.e., under the pressure areas). The same meaning is used here as for watches. The feature “water-resistant” means that the touch-sensitive switching apparatus is at least protected from splashing water so that this cannot penetrate the apparatus. The touch-sensitive switching apparatus is preferably watertight up to 2 atm, preferably up to 3 atm, preferably up to 5 atm, or even up to 10 atm, which prevents moisture from being able to penetrate the touch-sensitive switching apparatus even when external pressure is applied.

As a rule, the touch-sensitive switching apparatus itself is not yet suitable for triggering signals. However, it can be affixed to the touch display of a control apparatus equipped with a control program with predefined activation areas on the touch display corresponding to the pressure areas and which trigger a function when touched. The control apparatus can also control a device without the touch-sensitive switching apparatus, but liquid on the touch display could inadvertently activate functions. However, if the touch-sensitive switching apparatus is arranged on the touch display to match the activation areas, safe control is possible even in the event of spilled liquids.

By pressing down the pressure area, the finger approaches the capacitive sensor of the touch display. The capacitive sensor can detect this and thus triggers a touch event in the control apparatus. A liquid spilled on the touch-sensitive switching apparatus cannot trigger a false touch event with this simple switching apparatus as it is kept at a distance from the touch display by each activation element in the relevant area.

A control apparatus according to one or more example embodiments comprises a (preferably capacitive) touch display and a touch-sensitive switching apparatus according to one or more example embodiments which is applied to the touch display. It is preferably affixed via a (preferably transparent) adhesive.

In practice, each activation element of the touch-sensitive switching apparatus (which is essentially a keyboard on a control apparatus) should have a non-conductive, water-resistant, (highly) transparent, and rigid upper side (pressure area) and a flexible edge (spacing area), which should also be as transparent as possible. This spacing area allows the upper side to be pressed down onto the touch display but keeps it at a distance without external pressure. The thickness of the spacing area should be measured in such a manner that a contact pressure of at least 0.5 N, in particular at least 1 N, is required to lower the pressure area completely so that accidental activation cannot occur due to accidental liquids.

The capacitive touch-sensor of the touch display should preferably be configured for a “mutual” measurement, which enables multitouch operation in areas in which no buttons are affixed. Apart from the existing display control and the touch controller, essentially no additional hardware is required, so that theoretically a commercially available tablet computer and the touch-sensitive switching apparatus according to one or more example embodiments can be used to provide a reliable control device.

A method according to one or more example embodiments is used for the production of a control apparatus according to one or more example embodiments. It comprises the following steps:
Provision of a touch-sensitive switching apparatus according to one or more example embodiments,
Provision of a computing system with a touch display,
Specification of an arrangement area for the touch-sensitive switching apparatus on the touch display,
Application, preferably affixing, of the touch-sensitive switching apparatus to the touch display in its arrangement area.

The computing system with a touch display can be, for example, a specially manufactured control device, or a commercially available tablet computer with corresponding software. As aforementioned, essentially the computing system already constitutes a control apparatus (known in the prior art), but it is still vulnerable to liquids on the touch display. In order to obtain a safe control apparatus according to one or more example embodiments, the touch-sensitive switching apparatus must still be combined with the computing system.

The software of the computing system specifies the location of the areas on the touch display which must be touched to activate functions. The touch-sensitive switching apparatus is formed so that it can be precisely positioned on the touch display in such a manner that these areas can be touched via the activation elements. This is the attachment area of the touch-sensitive switching apparatus on the touch display.

If the touch-sensitive switching apparatus above the touch display is positioned precisely above the arrangement area, it can be applied there. For example, a protective film can be removed from an adhesive layer in the application area and the touch-sensitive switching apparatus can be affixed to the touch display.

Further, particularly advantageous embodiments and developments of the invention will emerge from the dependent claims and the following description, it being possible for the claims of one category of claims to also be developed analogously to the claims and parts of the description relating to another category of claims, and in particular also for individual features of different exemplary embodiments or variants to be combined to form new exemplary embodiments or variants.

A preferred touch-sensitive switching apparatus is characterized in that the attachment area, spacing areas and pressure areas (also activation areas) of the touch-sensitive switching apparatus are manufactured as a single-piece element. The element is preferably made of a transparent, elastic material, in particular silicone. For example, this element may be manufactured from a transparent, elastic plastic using an injection molding method or a casting method. It is preferable that the touch-sensitive switching apparatus is formed from a transparent, electrically non-conductive, water-resistant film in which the activation elements are formed as protrusions.

The vertical distance between the pressure area and the underside of the attachment area should be large enough that simply placing a finger on the surface does not generate a touch signal on the touch display below the pressure area (i.e., in the area corresponding to the vertical projection of the pressure area). In absolute terms, the vertical distance between the pressure area and the underside of the attachment area is preferably greater than 1 mm, in particular greater than 3 mm, or even greater than 5 mm. The thickness of the pressure area should be large enough that when the pressure area is pressed down completely (i.e., when it touches a touch display), a finger generates a touch signal on the surface of the touchscreen below the pressure area. In absolute terms, the thickness of the pressure area is preferably less than 2 mm, in particular less than 1 mm, or even less than 0.5 mm. However, the force with which the pressure area is to be pressed down should not be so small that a liquid on the touch-sensitive switching apparatus can press down the pressure area. Therefore, the pressure area and spacing area should preferably be thicker than 0.05 mm, preferably thicker than 0.1 mm.

A preferred touch-sensitive switching apparatus is characterized in that at least the surface of the upper side of the pressure areas, preferably the entire touch-sensitive switching apparatus, is made of an insulating material. A preferred insulating material has a specific resistance greater than 108 Ω·cm.

A preferred touch-sensitive switching apparatus comprises an adhesive layer, preferably double-sided adhesive tape, on the underside of the attachment area. It is preferable that the adhesive layer is transparent and, in particular, electrically non-conductive (i.e., it also constitutes an insulating material, see above). It should be water-insoluble and applied to the attachment area in such a manner that the touch-sensitive switching apparatus is also water-resistant at the adhesive point when affixed to a touch display.

A preferred touch-sensitive switching apparatus is characterized in that the pressure areas are more rigid in design than the spacing areas. It is preferable that the spacing areas (at least when the pressure area is pressed down) exert a force of at least 0.5 N, preferably at least 1 N, in the direction of the upper side on the respective pressure areas. This means that a contact pressure of at least 0.5 N (or at least 1 N) is required to lower the upper side so that accidental activation cannot occur due to applied liquids.

A preferred touch-sensitive switching apparatus is characterized in that at least one activation element has a number of haptic elements in the pressure area, preferably as a pattern of a number of indentations and/or protrusions on the surface of the pressure area, in particular in the form of characters or a Braille pattern. This has the advantage that, via the haptic feedback, a user can find the activation elements without looking, for example, when a patient is not to be let out of sight during operation. For example, characters such as “+” and “−” are recognized by the fingertips and the position of a patient table can be finely adjusted using the corresponding buttons while the corresponding activation elements are operated blindly. The haptic elements can be applied to a pressure area, in particular affixed, or they can also be formed by a corresponding molding on the surface of the pressure area. For example, when forming a silicon mat with a correspondingly designed shape, the pressure areas can be directly provided with haptic elements.

A preferred touch-sensitive switching apparatus is characterized in that at least one pressure area has at least one electrically conductive contact element on its underside. Preferably, there is therefore another layer of other material, preferably of an insulating material, over the contact element. It is preferable that this contact element comprises an (in particular micrometer-thin) layer of conductive material, in particular copper in the form of a meandering loop or a mesh, or of transparent indium tin oxide (ITO), which is applied to the underside of the pressure area. This additional layer ensures that the conductive surface always comes very close to the underlying glass, regardless of the thickness of the button and any gloves the user may be wearing, and thus provides a very good measurement value for the capacitive sensor. At the same time, good transparency is maintained.

According to a preferred embodiment, the pressure area is penetrated by a conductive element which is surrounded by non-conductive material on the surface of the pressure area. In this embodiment, the pressure area therefore has an electrically conductive area on the surface which can conduct current to the underside of the pressure area. This through-contacting element provides a connection with the operator—if the operator is not wearing gloves—and can in this case result in further improved capacitive measurement.

A preferred touch-sensitive switching apparatus is characterized in that the at least one contact element of a pressure area is electrically connected to a signal line which leads from the contact element to the attachment area. This has the advantage that the capacitive signal generated by the contact element when a finger is placed on a touch display can be registered by the display under the attachment area. Here, the relevant area of a touch display under the attachment area can be sensitive in design and can then register a touch when a finger is placed on the pressure area (without pressing the area down). This sensitive area should not be used for the activation of critical functions (as a liquid could also generate a signal), but auxiliary functions can be activated, such as for example, switching on a light or activating a touch area of the touch display under the relevant pressure area. Essentially, this special function can be used in the same way as hovering a mouse pointer. It is also preferable that the signal line leads from the attachment area to a pressure detection unit which is designed to measure pressure on the pressure area based on signals on the signal line, preferably regardless of the touch display.

A preferred touch-sensitive switching apparatus is characterized in that an activation element has at least two contact elements below the pressure area which overlap in vertical projection and are kept at a distance from one another. Both contact elements are preferably made of a transparent material, in particular ITO layers. The distance between the contact elements is preferably achieved by spacers, which are preferably made of a transparent, flexible plastic. Contact elements and, if applicable, spacers (in particular, their plastic) are preferably designed in such a manner that the conductive closing elements make contact at approximately the same contact pressure as the entire button. The contact elements are therefore arranged in such a manner that they do not touch one another when the activation element is not actuated and form a conductive closing element.

Signal lines preferably lead from the two contact elements to a pressure detection unit. The contact elements can therefore be monitored by the pressure detection unit. This makes it possible to determine whether the contact elements are touching. An additional insulating layer can be arranged between the contact elements. This enables a pressure signal to be detected independently of the touch display. This can be used for redundancy or monitoring.

In order to be able to clearly determine which activation elements have been pressed, it is preferable that the signal lines of different activation elements are attached separately, i.e. independently of one another, to the pressure detection unit. Alternatively or in addition, the contact elements may differ from one another in terms of individual resistance values, the resistance values preferably being selected in such a manner that even in the case of a parallel connection and/or series connection of the contact elements of different activation elements (i.e., several activation elements pressed), a clear assignment of the pressed activation elements is achieved. This can be achieved, for example, by the resistors each having different a2n resistance values each with different n values. In this preferred variant, a reduced number of measuring lines suffices.

The pressure detection unit and the controller of the touch display should be completely separate so that no single fault in one of the controllers can spread to the other controller. They should then preferably be connected to control elements which compare the two measurement results with one another and thus enable a self-test.

With these contact elements, a two-stage switch can also be implemented, the force to contact the contact elements preferably being greater or less than the force to press down the pressure area. When the contact elements are contacted, a different function can be triggered than when a touch display is touched.

A preferred control apparatus is configured in such a manner that surfaces of the touch display which are covered (intentionally) by an activation element are designed to trigger at least one function. This means that the touch display is sensitive under the pressure areas of such activation elements, and that pressing down on the relevant pressure area with a finger on the relevant surface can trigger an activation signal. It is preferable that the control apparatus is configured in such a manner that multitouch operation is possible in areas which are not covered by an activation element. However, the activation of potentially dangerous functions should not be possible as a result.

A preferred control apparatus is configured in such a manner that surfaces of the touch display which are covered by an attachment area are designed to trigger a function, and the touch-sensitive switching apparatus comprises a signal line from a contact element in a pressure area to the relevant part of the attachment area. This allows the capacitive signal generated by the contact element of a finger placed on the touch display to be registered by the touch display in the relevant area of the attachment area and functions activated or deactivated as a result. However, these should not be potentially dangerous as spilled liquid could also activate these functions. It is preferable that this function is an auxiliary function for a control function which is activated by pressing down the relevant pressure area, for example, a light or a special display.

A preferred control apparatus is characterized in that an area of the touch display has several touch-activation areas under a pressure area, i.e., areas in which the touch display registers a signal after being touched and can thus trigger a control command. It is preferable that the touch-activation areas are arranged next to one another, preferably in a straight line, and simulate a slider. “Next to one another” refers only to the relative arrangement in relation to one another, so from the user's perspective this term means both side by side, one above the other, and diagonally next to one another. This makes it possible to activate several different signals (or control commands) by pressing on the pressure area, for example by continuously raising or lowering a control parameter employing a “swipe” motion.

Example embodiments enable the operation of a capacitive touchscreen even when highly exposed to conductive liquids. In addition, the touch-sensitive switching apparatus can be manufactured easily and inexpensively, which is a further advantage. The safety function with a closing element in each individual button allows for an almost arbitrarily high resolution and thus buttons located immediately next to one another. Depending on the embodiment, in addition to a capacitive touch event, a resistive touch event which can be measured independently can also be triggered.

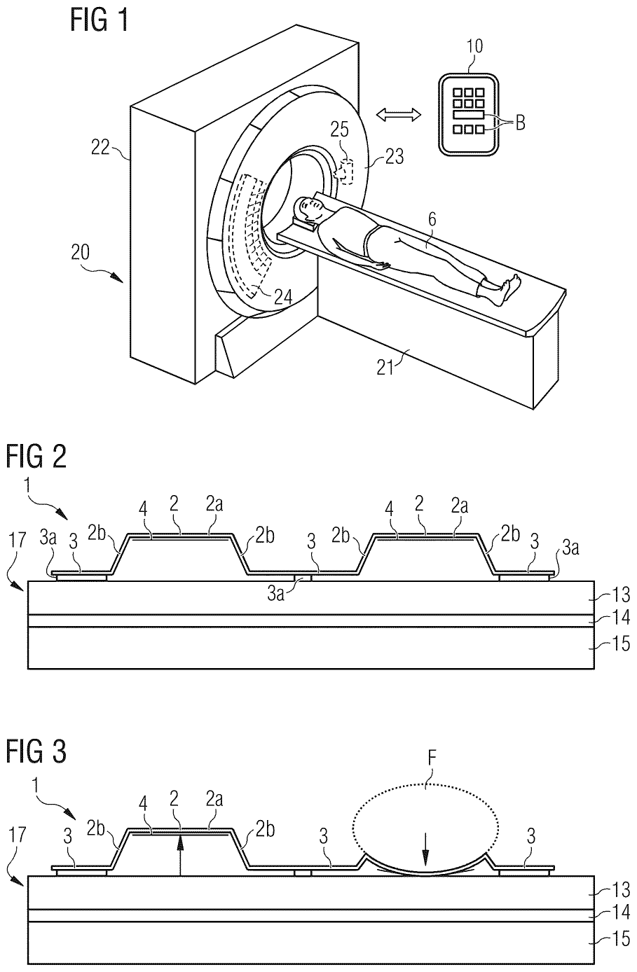

FIG. 1 shows a computed tomography system (CT system 20), which is controlled by a control apparatus 10, as an example. It is equipped with a radiation detector 24 and an X-ray source 25, the X-ray source 25 being designed to expose the radiation detector 24 to X-rays. The CT system 20 shown comprises a gantry 22 with a rotor 23, which in turn comprises the X-ray source 25 and the radiation detector 24. The control apparatus 10 can control the functions of this gantry 22 and activate the radiation source 25 as a result of pressure on one of the buttons B on the touch display in order to examine a patient P lying on the patient table 21.

FIG. 2 shows an example of a touch-sensitive switching apparatus 1 according to one or more example embodiments in side view. This touch-sensitive switching apparatus 1 shows a display 13, a touch sensor 14 and a protective glass plate 15 which symbolize a touch display 17 of a control apparatus 10, as shown, for example, in FIG. 1. The touch-sensitive switching apparatus 1 supplements this control apparatus 10 so that safe control is possible in spite of spilled liquids.

The touch-sensitive switching apparatus 1 comprises an attachment area 3 with the underside of which the touch-sensitive switching apparatus 1 is attached to the touch display 17 via an adhesive layer 3a. In addition, two activation elements 2 are visible here, which comprise a transparent pressure area 2a with an electrically conductive contact element 4 and an elastic spacing area 2b. This spacing area 2b completely surrounds the pressure area 2a and keeps it away from the plane of the attachment area. The touch-sensitive switching apparatus 1 is transparent, at least in the pressure area 2a, so that the underlying touch display 17 is visible. The surface of the touch-sensitive switching apparatus 1 is water-resistant, preferably watertight, so that no liquid can penetrate under the pressure area 2a from this surface. The adhesive layer 3a on the underside of the attachment area 3, for example double-sided adhesive tape, is transparent and electrically non-conductive.

In the touch-sensitive switching apparatus 1, the attachment area 3, spacing areas 2b and pressure areas 2a are manufactured as a single-piece element from a transparent, elastic material, for example, silicone. The activation elements 2 are formed as protrusions there. The surface of the upper side of the entire touch-sensitive switching apparatus 1 is therefore made of an insulating material.

The contact element 4 comprises a layer of conductive material, for example, copper or indium tin oxide, which is applied to the underside of the pressure area 2.1. The contact element can, for example, consist of a meandering shape or a mesh of micrometer-thin copper wire, or be applied as a layer of transparent indium tin oxide. This additional layer ensures that the conductive surface always comes very close to the underlying glass, regardless of the thickness of the button and any gloves the user may be wearing and thus provides a very good measurement value for the capacitive touch sensor 14. At the same time, a very high level of transparency is maintained.

FIG. 3 shows an example of the function of a touch-sensitive switching apparatus 1 according to one or more example embodiments in FIG. 2 in side view. The left pressure area 2a is kept at a distance from the touch display 17 by the spacing area 2b (arrow). A force is required to press the pressure area down. The right pressure area 2a is pressed down by a finger F and produces a desired contact between the pressure area 2a or its contact element 4 and the display 13. By pressing the pressure area 2a down against the force of the spacing area 2b, the finger F or the contact element 4 approaches the capacitive touch sensor 14, which can detect this. In this manner, a touch event is triggered. Moisture on the touch-sensitive switching apparatus 1 cannot trigger a false touch event as the pressure area 2a is kept at a distance from the touch display 17 by the spacing area 2b.

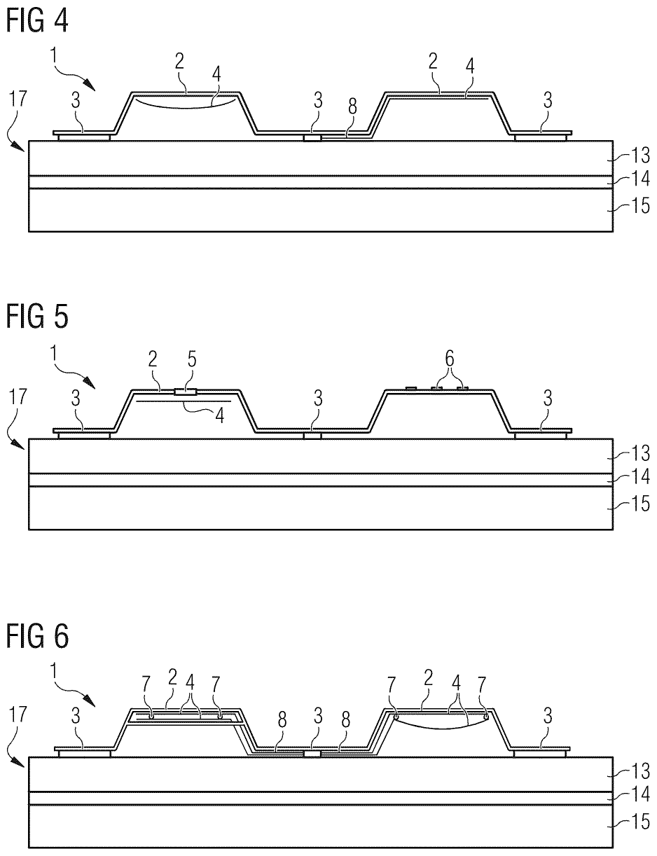

FIG. 4 shows a variation of FIG. 2 as a further example of a touch-sensitive switching apparatus 1 according to one or more example embodiments in side view. A curved contact element 4 is shown on the left, and on the right a contact element 4 which is electrically connected to a signal line 8 leading from the contact element 4 to the attachment area 3. There it can apply a capacitive touch signal to the attachment area 3, which can be registered by a sensitive area of the touch sensor 14 there. The signal line 8 causes the mere placement of a finger F to trigger capacitive touch detection of a secondary contact in the second area. This second area can also be used for several buttons at the same time. A reasonable response to placing a finger F on a button is an optical indicator below or in the vicinity of the transparent buttons which lets the user know that the device is ready for further input.

FIG. 5 shows a further variation of FIG. 2 as another example of a touch-sensitive switching apparatus 1 according to one or more example embodiments in side view. On the left, the pressure area 2a is penetrated by a conductive element 5, which is surrounded by non-conductive material on the surface of the pressure area 2a. This through-contacting element provides a connection with the operator —if the operator is not wearing gloves —and can in this case result in further improved capacitive measurement. In the case of the left activation element 2, the pressure area 2a has haptic elements 6 which form a pattern which can be felt with the fingertips. When, for example, a user has to observe a patient while operating the device, such haptic feedback is highly advantageous. For blind operation, it can be assumed that buttons located directly next to one another are clearly preferable.

FIG. 6 shows a further variation of FIG. 2 as an example of a touch-sensitive switching apparatus 1 according to one or more example embodiments in side view. Here, the activation elements 2 have two contact elements 4 below the pressure area 2a which overlap in vertical projection and are kept at a distance from one another by spacers 7 so that they do not touch one another when the activation element 2 is not actuated. When they touch, they form a conductive closing element, it being possible for signal lines 8 from the two contact elements 4 to constitute this contact, for example, via a current which can then flow. On the left, two parallel contact elements 4 are shown; on the right, a straight and a curved contact element 4 are shown, the contact of which requires more force than the establishment of contact on the left.

The spacers 7 are preferably made of a transparent flexible plastic which is designed in such a manner that the conductive closing elements make contact at approximately the same contact pressure as the entire button. The conductive layers (contact elements 4) can be made of ITO or other conductive transparent materials. The signal lines 8 are preferably routed between the underside of the attachment area 3 and the adhesive layer 3a. Inconspicuous integration is thus provided, above all when the buttons are placed at the edge of the display.

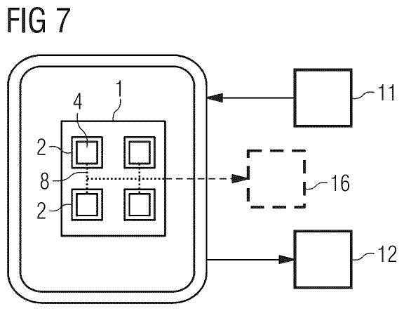

FIG. 7 shows a control apparatus with a touch-sensitive switching apparatus 1 according to one or more example embodiments. In the prior art it is known that a touch display 17 has a display controller 11 which controls the display on the touch display 17, and a touch controller 12, which registers touch on the touch display 17 via the touch sensor 14. These controllers are sufficient for normal control.

A dashed line indicates an addition in the form of a pressure detection unit 16 which functionally optimizes the embodiment shown in FIG. 6. The signal lines 8 of the contact elements 4 lead to this pressure detection unit 16 and can transmit signals to the pressure detection unit 16 when the relevant contact elements 4 make contact. It is preferable that the signal lines 8 of different activation elements are attached separately to the pressure detection unit 16 for clear assignment so that the individual activation elements can be resolved. If signal lines to the pressure detection unit 16 are to be saved, the contact elements 4 can differ from one another with regard to individual resistance values. Preferably, the pressure detection unit 16 is completely separated from the display controller 11 and the touch controller 12 so that no single fault in one of the controllers can spread to the other controller.

Finally, it should be noted once again that the invention described in detail above only concerns exemplary embodiments which can be modified in many different ways by a person skilled in the art without departing from the scope of the invention. Furthermore, the use of the indefinite article “a” or “an” does not exclude the possibility that the relevant features may also be present multiple times. Likewise, terms like “unit” do not exclude the possibility that the relevant components may consist of several interacting subcomponents, which may also be spatially distributed. The term “a number” is to be read as “at least one”. Independent of the grammatical term usage, individuals with male, female or other gender identities are included within the term.

It will be understood that, although the terms first, second, etc. may be used herein to describe various elements, components, regions, layers, and/or sections, these elements, components, regions, layers, and/or sections, should not be limited by these terms. These terms are only used to distinguish one element from another. For example, a first element could be termed a second element, and, similarly, a second element could be termed a first element, without departing from the scope of example embodiments. As used herein, the term “and/or,” includes any and all combinations of one or more of the associated listed items. The phrase “at least one of” has the same meaning as “and/or”.

Spatially relative terms, such as “beneath,” “below,” “lower,” “under,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below,” “beneath,” or “under,” other elements or features would then be oriented “above” the other elements or features. Thus, the example terms “below” and “under” may encompass both an orientation of above and below. The device may be otherwise oriented (rotated 90 degrees or at other orientations) and the spatially relative descriptors used herein interpreted accordingly. In addition, when an element is referred to as being “between” two elements, the element may be the only element between the two elements, or one or more other intervening elements may be present.

Spatial and functional relationships between elements (for example, between modules) are described using various terms, including “on,“ ”connected,” “engaged,” “interfaced,” and “coupled.” Unless explicitly described as being “direct,” when a relationship between first and second elements is described in the disclosure, that relationship encompasses a direct relationship where no other intervening elements are present between the first and second elements, and also an indirect relationship where one or more intervening elements are present (either spatially or functionally) between the first and second elements. In contrast, when an element is referred to as being “directly” on, connected, engaged, interfaced, or coupled to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list. Also, the term “example” is intended to refer to an example or illustration.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

It is noted that some example embodiments may be described with reference to acts and symbolic representations of operations (e.g., in the form of flow charts, flow diagrams, data flow diagrams, structure diagrams, block diagrams, etc.) that may be implemented in conjunction with units and/or devices discussed above. Although discussed in a particular manner, a function or operation specified in a specific block may be performed differently from the flow specified in a flowchart, flow diagram, etc. For example, functions or operations illustrated as being performed serially in two consecutive blocks may actually be performed simultaneously, or in some cases be performed in reverse order. Although the flowcharts describe the operations as sequential processes, many of the operations may be performed in parallel, concurrently or simultaneously. In addition, the order of operations may be re-arranged. The processes may be terminated when their operations are completed, but may also have additional steps not included in the figure. The processes may correspond to methods, functions, procedures, subroutines, subprograms, etc.

Specific structural and functional details disclosed herein are merely representative for purposes of describing example embodiments. The present invention may, however, be embodied in many alternate forms and should not be construed as limited to only the embodiments set forth herein.

In addition, or alternative, to that discussed above, units and/or devices according to one or more example embodiments may be implemented using hardware, software, and/or a combination thereof. For example, hardware devices may be implemented using processing circuitry such as, but not limited to, a processor, Central Processing Unit (CPU), a Graphics Processing Unit (GPU), a controller, an arithmetic logic unit (ALU), a digital signal processor, a microcomputer, a field programmable gate array (FPGA), a System-on-Chip (SoC), a programmable logic unit, a microprocessor, or any other device capable of responding to and executing instructions in a defined manner. Portions of the example embodiments and corresponding detailed description may be presented in terms of software, or algorithms and symbolic representations of operation on data bits within a computer memory. These descriptions and representations are the ones by which those of ordinary skill in the art effectively convey the substance of their work to others of ordinary skill in the art. An algorithm, as the term is used here, and as it is used generally, is conceived to be a self-consistent sequence of steps leading to a desired result. The steps are those requiring physical manipulations of physical quantities. Usually, though not necessarily, these quantities take the form of optical, electrical, or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind that all of these and similar terms are to be associated with the appropriate physical quantities and are merely convenient labels applied to these quantities. Unless specifically stated otherwise, or as is apparent from the discussion, terms such as “processing” or “computing” or “calculating” or “determining” of “displaying” or the like, refer to the action and processes of a computer system, or similar electronic computing device/hardware, that manipulates and transforms data represented as physical, electronic quantities within the computer system's registers and memories into other data similarly represented as physical quantities within the computer system memories or registers or other such information storage, transmission or display devices.

In this application, including the definitions below, the term ‘module’ or the term ‘controller’ may be replaced with the term ‘circuit.’ The term ‘module’ may refer to, be part of, or include processor hardware (shared, dedicated, or group) that executes code and memory hardware (shared, dedicated, or group) that stores code executed by the processor hardware.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

Software may include a computer program, program code, instructions, or some combination thereof, for independently or collectively instructing or configuring a hardware device to operate as desired. The computer program and/or program code may include program or computer-readable instructions, software components, software modules, data files, data structures, and/or the like, capable of being implemented by one or more hardware devices, such as one or more of the hardware devices mentioned above. Examples of program code include both machine code produced by a compiler and higher level program code that is executed using an interpreter.

For example, when a hardware device is a computer processing device (e.g., a processor, Central Processing Unit (CPU), a controller, an arithmetic logic unit (ALU), a digital signal processor, a microcomputer, a microprocessor, etc.), the computer processing device may be configured to carry out program code by performing arithmetical, logical, and input/output operations, according to the program code. Once the program code is loaded into a computer processing device, the computer processing device may be programmed to perform the program code, thereby transforming the computer processing device into a special purpose computer processing device. In a more specific example, when the program code is loaded into a processor, the processor becomes programmed to perform the program code and operations corresponding thereto, thereby transforming the processor into a special purpose processor.

Software and/or data may be embodied permanently or temporarily in any type of machine, component, physical or virtual equipment, or computer storage medium or device, capable of providing instructions or data to, or being interpreted by, a hardware device. The software also may be distributed over network coupled computer systems so that the software is stored and executed in a distributed fashion. In particular, for example, software and data may be stored by one or more computer readable recording mediums, including the tangible or non-transitory computer-readable storage media discussed herein.

Even further, any of the disclosed methods may be embodied in the form of a program or software. The program or software may be stored on a non-transitory computer readable medium and is adapted to perform any one of the aforementioned methods when run on a computer device (a device including a processor). Thus, the non-transitory, tangible computer readable medium, is adapted to store information and is adapted to interact with a data processing facility or computer device to execute the program of any of the above mentioned embodiments and/or to perform the method of any of the above mentioned embodiments.

Example embodiments may be described with reference to acts and symbolic representations of operations (e.g., in the form of flow charts, flow diagrams, data flow diagrams, structure diagrams, block diagrams, etc.) that may be implemented in conjunction with units and/or devices discussed in more detail below. Although discussed in a particular manner, a function or operation specified in a specific block may be performed differently from the flow specified in a flowchart, flow diagram, etc. For example, functions or operations illustrated as being performed serially in two consecutive blocks may actually be performed simultaneously, or in some cases be performed in reverse order.

According to one or more example embodiments, computer processing devices may be described as including various functional units that perform various operations and/or functions to increase the clarity of the description. However, computer processing devices are not intended to be limited to these functional units. For example, in one or more example embodiments, the various operations and/or functions of the functional units may be performed by other ones of the functional units. Further, the computer processing devices may perform the operations and/or functions of the various functional units without sub-dividing the operations and/or functions of the computer processing units into these various functional units.

Units and/or devices according to one or more example embodiments may also include one or more storage devices. The one or more storage devices may be tangible or non-transitory computer-readable storage media, such as random access memory (RAM), read only memory (ROM), a permanent mass storage device (such as a disk drive), solid state (e.g., NAND flash) device, and/or any other like data storage mechanism capable of storing and recording data. The one or more storage devices may be configured to store computer programs, program code, instructions, or some combination thereof, for one or more operating systems and/or for implementing the example embodiments described herein. The computer programs, program code, instructions, or some combination thereof, may also be loaded from a separate computer readable storage medium into the one or more storage devices and/or one or more computer processing devices using a drive mechanism. Such separate computer readable storage medium may include a Universal Serial Bus (USB) flash drive, a memory stick, a Blu-ray/DVD/CD-ROM drive, a memory card, and/or other like computer readable storage media. The computer programs, program code, instructions, or some combination thereof, may be loaded into the one or more storage devices and/or the one or more computer processing devices from a remote data storage device via a network interface, rather than via a local computer readable storage medium. Additionally, the computer programs, program code, instructions, or some combination thereof, may be loaded into the one or more storage devices and/or the one or more processors from a remote computing system that is configured to transfer and/or distribute the computer programs, program code, instructions, or some combination thereof, over a network. The remote computing system may transfer and/or distribute the computer programs, program code, instructions, or some combination thereof, via a wired interface, an air interface, and/or any other like medium.

The one or more hardware devices, the one or more storage devices, and/or the computer programs, program code, instructions, or some combination thereof, may be specially designed and constructed for the purposes of the example embodiments, or they may be known devices that are altered and/or modified for the purposes of example embodiments.

A hardware device, such as a computer processing device, may run an operating system (OS) and one or more software applications that run on the OS. The computer processing device also may access, store, manipulate, process, and create data in response to execution of the software. For simplicity, one or more example embodiments may be exemplified as a computer processing device or processor; however, one skilled in the art will appreciate that a hardware device may include multiple processing elements or processors and multiple types of processing elements or processors. For example, a hardware device may include multiple processors or a processor and a controller. In addition, other processing configurations are possible, such as parallel processors.

The computer programs include processor-executable instructions that are stored on at least one non-transitory computer-readable medium (memory). The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc. As such, the one or more processors may be configured to execute the processor executable instructions.

The computer programs may include: (i) descriptive text to be parsed, such as HTML (hypertext markup language) or XML (extensible markup language), (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Haskell, Go, SQL, R, Lisp, Java®, Fortran, Perl, Pascal, Curl, OCaml, Javascript®, HTML5, Ada, ASP (active server pages), PHP, Scala, Eiffel, Smalltalk, Erlang, Ruby, Flash®, Visual Basic®, Lua, and Python®.

Further, at least one example embodiment relates to the non-transitory computer-readable storage medium including electronically readable control information (processor executable instructions) stored thereon, configured in such that when the storage medium is used in a controller of a device, at least one embodiment of the method may be carried out.

The computer readable medium or storage medium may be a built-in medium installed inside a computer device main body or a removable medium arranged so that it can be separated from the computer device main body. The term computer-readable medium, as used herein, does not encompass transitory electrical or electromagnetic signals propagating through a medium (such as on a carrier wave); the term computer-readable medium is therefore considered tangible and non-transitory. Non-limiting examples of the non-transitory computer-readable medium include, but are not limited to, rewriteable non-volatile memory devices (including, for example flash memory devices, erasable programmable read-only memory devices, or a mask read-only memory devices); volatile memory devices (including, for example static random access memory devices or a dynamic random access memory devices); magnetic storage media (including, for example an analog or digital magnetic tape or a hard disk drive); and optical storage media (including, for example a CD, a DVD, or a Blu-ray Disc). Examples of the media with a built-in rewriteable non-volatile memory, include but are not limited to memory cards; and media with a built-in ROM, including but not limited to ROM cassettes; etc. Furthermore, various information regarding stored images, for example, property information, may be stored in any other form, or it may be provided in other ways.

The term code, as used above, may include software, firmware, and/or microcode, and may refer to programs, routines, functions, classes, data structures, and/or objects. Shared processor hardware encompasses a single microprocessor that executes some or all code from multiple modules. Group processor hardware encompasses a microprocessor that, in combination with additional microprocessors, executes some or all code from one or more modules. References to multiple microprocessors encompass multiple microprocessors on discrete dies, multiple microprocessors on a single die, multiple cores of a single microprocessor, multiple threads of a single microprocessor, or a combination of the above.

Shared memory hardware encompasses a single memory device that stores some or all code from multiple modules. Group memory hardware encompasses a memory device that, in combination with other memory devices, stores some or all code from one or more modules.

The term memory hardware is a subset of the term computer-readable medium. The term computer-readable medium, as used herein, does not encompass transitory electrical or electromagnetic signals propagating through a medium (such as on a carrier wave); the term computer-readable medium is therefore considered tangible and non-transitory. Non-limiting examples of the non-transitory computer-readable medium include, but are not limited to, rewriteable non-volatile memory devices (including, for example flash memory devices, erasable programmable read-only memory devices, or a mask read-only memory devices); volatile memory devices (including, for example static random access memory devices or a dynamic random access memory devices); magnetic storage media (including, for example an analog or digital magnetic tape or a hard disk drive); and optical storage media (including, for example a CD, a DVD, or a Blu-ray Disc). Examples of the media with a built-in rewriteable non-volatile memory, include but are not limited to memory cards; and media with a built-in ROM, including but not limited to ROM cassettes; etc. Furthermore, various information regarding stored images, for example, property information, may be stored in any other form, or it may be provided in other ways.

The apparatuses and methods described in this application may be partially or fully implemented by a special purpose computer created by configuring a general purpose computer to execute one or more particular functions embodied in computer programs. The functional blocks and flowchart elements described above serve as software specifications, which can be translated into the computer programs by the routine work of a skilled technician or programmer.

Although described with reference to specific examples and drawings, modifications, additions and substitutions of example embodiments may be variously made according to the description by those of ordinary skill in the art. For example, the described techniques may be performed in an order different with that of the methods described, and/or components such as the described system, architecture, devices, circuit, and the like, may be connected or combined to be different from the above-described methods, or results may be appropriately achieved by other components or equivalents.

1. A touch-sensitive switching apparatus for a control device with a touch display, the touch-sensitive switching apparatus comprising:
an attachment area, an underside of the attachment area permitting the touch-sensitive switching apparatus to be attached to the touch display; and
a plurality of activation elements, each activation element including,
a transparent pressure area with an electrically conductive contact element, and
an elastic spacing area completely surrounding the pressure area and spacing the pressure area from a plane of the attachment area, wherein the touch-sensitive switching apparatus is transparent, at least in the pressure area, such that an underlying touch display is visible, wherein a surface of the touch-sensitive switching apparatus is at least water-resistant to prevent liquid penetration under the pressure area from the surface of the touch-sensitive switching apparatus.

2. The touch-sensitive switching apparatus of claim 1, wherein the attachment area, spacing areas and pressure areas of the touch-sensitive switching apparatus are manufactured as a single-piece element.

3. The touch-sensitive switching apparatus of claim 1, wherein at least a surface of an upper side of the pressure areas is made of an insulating material.

4. The touch-sensitive switching apparatus of claim 1, further comprising:
an adhesive layer on the underside of the attachment area.

5. The touch-sensitive switching apparatus of claim 1, wherein the pressure areas are more rigid than the spacing areas.

6. The touch-sensitive switching apparatus of claim 1, wherein at least one activation element has a number of haptic elements in the pressure area.

7. The touch-sensitive switching apparatus of claim 1, wherein at least one pressure area includes at least one electrically conductive contact element on the underside.

8. The touch-sensitive switching apparatus of claim 7, wherein the at least one contact element of a pressure area is electrically connected to a signal line which leads from the contact element to the attachment area.

9. The touch-sensitive switching apparatus of claim 7, wherein an activation element includes at least two contact elements below the pressure area which overlap in a vertical projection and are held at a distance from one another.

10. A control apparatus comprising:
a touch display; and
the touch-sensitive switching apparatus of claim 1, the touch display being affixed to the touch-sensitive switching apparatus by an adhesive.

11. The control apparatus of claim 10, wherein surfaces of the touch display are overlapped by at least one of the activation elements and are configured to trigger at least one function.

12. The control apparatus of claim 11, wherein the touch-sensitive switching apparatus comprises a signal line from one contact element in the associated pressure area to a relevant part of the attachment area.

13. The control apparatus of claim 10, wherein an area of the touch display has several touch activation areas under at least one of the pressure areas.

14. A method for manufacturing the control apparatus of claim 10, the method comprising:
providing the touch-sensitive switching apparatus;
providing a computing system with a touch display;
specifying an arrangement area for the touch-sensitive switching apparatus on the touch display; and
applying the touch-sensitive switching apparatus to the touch display in its arrangement area.

15. The touch-sensitive switching apparatus of claim 2, wherein the attachment area, spacing areas and pressure areas of the touch-sensitive switching apparatus are a transparent and elastic material.

16. The touch-sensitive switching apparatus of claim 15, wherein the touch-sensitive switching apparatus is formed from a transparent, electrically non-conductive, water-resistant film in which the activation elements are formed as protrusions.

17. The touch-sensitive switching apparatus of claim 4, wherein the adhesive layer is transparent and electrically non-conductive.

18. The touch-sensitive switching apparatus of claim 5, wherein the spacing areas exert a force of at least 0.5 N in a direction of an upper side on the respective pressure areas.

19. The touch-sensitive switching apparatus of claim 6, wherein the number of haptic elements are in a Braille pattern.

20. The touch-sensitive switching apparatus of claim 7, wherein the at least one contact element comprises a layer of conductive material applied to the underside of the pressure area.
